(19) United States
(12) Patent Application Publication
(10) Pub. No.: US 2018/0335447 A1
(43) Pub. Date: Nov. 22, 2018

(54) CONTACT PROBE AND INSPECTION JIG

(71) Applicant: YOKOWO CO., LTD., Tokyo (JP)

(72) Inventor: Tsugio YAMAMOTO, Tomioka-shi (JP)

(73) Assignee: YOKOWO CO., LTD., Tokyo (JP)

(21) Appl. No.: 15/982,099

(22) Filed: May 17, 2018

(30) Foreign Application Priority Data
May 17, 2017 (JP) 2017-097860

(51) Int. Cl. G01R 1/067; G01R 31/28; G01R 31/26; G01R 1/04; H01R 13/24

(52) U.S. Cl. CPC G01R 1/06722; G01R 31/2886; H01R 13/2421; G01R 1/0433; G01R 31/26

(57) ABSTRACT

A contact probe includes a tube which is electrically conductive, a plunger which is electrically conductive and disposed in the tube at one end of the tube, and a spring which is disposed in the tube and urges the plunger in a projection direction. The tube includes a slant portion on an inner circumferential surface of the tube. The slant portion is inclined with respect to an axial direction of the tube. A base portion comes into contact with the slant portion and an inclination of the plunger varies, when the plunger retracts.

### CROSS-REFERENCES TO RELATED APPLICATIONS

This patent application is based on and claims priority from Japanese Patent Application No. 2017-097860 filed on May 17, 2017, the entire contents of which are incorporated herein by reference.

### BACKGROUND

### 1. Field of the Invention

The present invention relates to a contact probe used for inspecting a measurement target device such as a semiconductor integrated circuit and an inspection jig including the contact probe.

### 2. Description of Related Art

JP-U-03-099364 discloses a contact probe including a tube and a plunger movable parallel with an axial direction of the tube.

In the structure of JP-U-03-099364, the plunger includes a small-diameter intermediate portion between a tip portion and a base portion. The small-diameter intermediate portion is required to have a length over a stroke length or more of the plunger. Thus, the small-diameter intermediate portion may become insufficient in strength, when the diameter of the plunger is reduced according to a diameter reduction of the contact probe. Furthermore, in the structure of JP-U-03-099364, since it is necessary to increase a thickness of a tip portion of the tube to which the plunger is to come into contact, a working operation of the tip portion of the tube would become difficult.

### SUMMARY

One or more embodiments relates to a contact probe that performs a scrub operation and an inspection jig that is equipped with the contact probe, in which a risk of strength reduction of a plunger would be lowered and a difficulty of a working operation of a tube would also be lowered.

In accordance with one or more embodiments, a contact probe includes a tube which is electrically conductive, a plunger which is electrically conductive and disposed in the tube at one end of the tube, and a spring which is disposed in the tube and urges the plunger in a projection direction. The tube includes a slant portion on an inner circumferential surface of the tube. The slant portion is inclined with respect to an axial direction of the tube. A base portion comes into contact with the slant portion and an inclination of the plunger varies, when the plunger retracts.

Other aspects and advantages of the invention will be apparent from the following description and the appended claims.

### BRIEF DESCRIPTION OF THE DRAWINGS

FIG. 1A is a sectional view of an inspection jig 1A according to a first embodiment.

FIG. 1B is a sectional view showing how an inspection is conducted using the inspection jig 1A.

FIG. 2 is a sectional view taken along line II-II in FIG. 1B.

FIG. 3A is a sectional view of an inspection jig 1B according to a second embodiment.

FIG. 3B is a sectional view showing how an inspection is conducted using the inspection jig 1B.

FIG. 4A is a sectional view of an inspection jig 1C according to a third embodiment.

FIG. 4B is a sectional view showing how an inspection is conducted using the inspection jig 1C.

FIG. 5A is a sectional view of an inspection jig 1D according to a fourth embodiment.

FIG. 5B is a sectional view showing how an inspection is conducted using the inspection jig 1D.

FIG. 6A is a sectional view of an inspection jig 1E according to a fifth embodiment.

FIG. 6B is a sectional view showing how an inspection is conducted using the inspection jig 1E.

FIG. 7A is a sectional view of an inspection jig 1F according to a sixth embodiment.

FIG. 7B is a sectional view showing how an inspection is conducted using the inspection jig 1F.

FIG. 8A is a sectional view of an inspection jig 1Z according to a comparative example.

FIG. 8B is a sectional view showing how an inspection is conducted using the inspection jig 1Z.

FIG. 9 is a sectional view taken along line IX-IX in FIG. 8B.

### DETAILED DESCRIPTION

Embodiments will be hereinafter described in detail with reference to the drawings. Sets of the same or equivalent constituent elements, members, etc. shown in the drawings are given the same reference symbols and will not be described redundantly as appropriate. The embodiments are just examples and are not intended to restrict the invention, and features described in the embodiments and combinations thereof need not always be essential to the invention.

### Embodiment 1

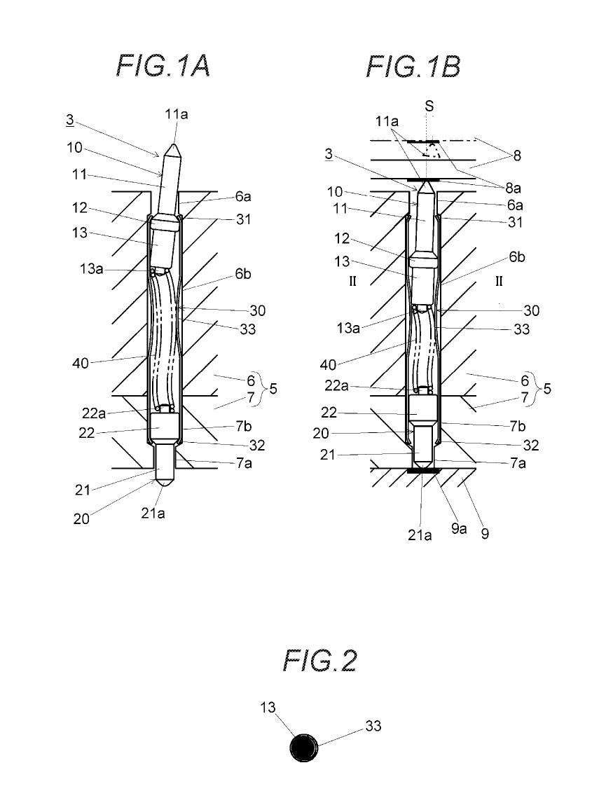

FIG. 1A is a sectional view of an inspection jig 1A according to a first embodiment, and FIG. 1B is a sectional view showing how an inspection is conducted using the inspection jig 1A. The inspection jig 1A is equipped with a contact probe 3 and an electrically insulative socket 5 which holds the contact probe 3 penetrating through it. Although in the illustrated example only one contact probe 3 is supported by the socket 5, plural contact probes 3 may be supported by the socket 5. The socket 5 is formed by combining a first socket 6 and a second socket 7 together and screwing them on each other into an integral body. A small-diameter hole 6a and a large-diameter hole 6b of the first socket 6 and a small-diameter hole 7a and a large-diameter hole 7b of the second socket 7 constitute a through-hole in which the contact probe 3 is set.

The contact probe 3 has a first plunger 10, a second plunger 20, a tube 30, and a spring 40. The first plunger 10 is a component for connection to an inspection target 8 shown in FIG. 1B. The second plunger 20 is a component for connection to an inspection board 9 shown in FIG. 1B. The tube 30 is a component that houses a base-side portion of the first plunger 10, a base-side portion of the second plunger 20, and the spring 40 inside. Each of the first plunger 10, the second plunger 20, and the tube 30 is a conductive metal body made of copper, a copper alloy, or the like.

The spring 40, which is a coil spring made of a common conductive metal material such as piano wire or stainless steel wire, urges the first plunger 10 and the second plunger 20 in such directions that they go away from each other and thereby gives them forces that cause them to come into contact with the inspection target 8 and the inspection board 9, respectively. The inspection target 8 is, for example, a semiconductor integrated circuit in which electrodes (in the illustrated example, electrode pads 8a) are arranged at prescribed intervals. The inspection board 9 has electrode pads 9a which are connected to a measuring instrument (not shown) and arranged at prescribed intervals.

The first plunger 10 has a tip-side cylinder portion 11 as a tip-side rod-shaped portion, a flange portion 12 as a drop-off-preventive large-diameter portion, and a base-side cylinder portion 13 as a base portion, which are arranged in this order from the tip side. The tip-side cylinder portion 11 penetrates through the small-diameter hole 6a of the first socket 6 and projects above the surface of the first socket 6. A tip portion of the tip-side cylinder portion 11 is a contact portion 11a which is tapered so as to assume a conical shape.

The flange portion 12 is larger in diameter than the tip-side cylinder portion 11 and housed in the tube 30. The outer diameter of the flange portion 12 is larger than the inner diameter of a narrowing portion 31 of the tube 30. Thus, the first plunger 10 is prevented from drop-off the tube 30 because of engagement between the flange portion 12 and the narrowing portion 31. The flange portion 12 is circular in a cross section taken perpendicularly to the longitudinal direction of the first plunger 10, and the outer diameter of the flange portion 12 is a little smaller than the inner diameter of the tube 30. The outer diameter and the width in the longitudinal direction of the first plunger 10 of the flange portion 12 are set so that as described later the first plunger 10 can be inclined with respect to the axial direction of the tube 30.

The base-side cylinder portion 13 is disposed inside the tube 30, is smaller in diameter than the flange portion 12, and is shaped like a cylinder that is approximately constant in diameter. When the first plunger 10 is inclined with respect to the axial direction of the tube 30 (stated roughly, the flange portion 12 serves as a supporting point), the bottom end of the outer circumferential surface of the base-side cylinder portion 13 comes into contact with the inner circumferential surface of the tube 30. Thus, the diameter and the length of the base-side cylinder portion 13 are set according to an inclination of the first plunger 10. The base surface of the base-side cylinder portion 13 is a flat surface that is perpendicular to the longitudinal direction of the first plunger 10, and is formed with a projection 13a. The projection 13a is fitted in the inner circumference of one end portion of the spring 40 and is thereby engaged with the spring 40. The first plunger 10 is inclined with respect to the axial direction of the tube 30 (described later).

The second plunger 20 has a tip-side cylinder portion 21 and a base-side cylinder portion 22, which are arranged in this order from the tip side. The tip-side cylinder portion 21 penetrates through and is guided by a small-diameter hole 7a of the second socket 7, and projects below the surface of the second socket 7. A tip portion of the tip-side cylinder portion 21 is a contact portion 21a which is tapered so as to assume a conical shape.

The base-side cylinder portion 22 is larger in diameter than the tip-side cylinder portion 21 and is housed in the tube 30. The outer diameter of the base-side cylinder portion 22 is larger than the inner diameter of a narrowing portion 32 of the tube 30. Thus, the second plunger 20 is prevented from drop-off the tube 30 because of engagement between the base-side cylinder portion 22 and the narrowing portion 32. The base surface of the base-side cylinder portion 22 is a flat surface that is perpendicular to the longitudinal direction of the second plunger 20, and is formed with a projection 22a. The projection 22a is engaged with the inner circumference of the other end portion of the spring 40.

The tube 30 is produced by forming narrowing portions 31-33 in a cylindrical metal pipe by known drawing. The portions, other than the narrowing portions 31-33, of the tube 30 have cylindrical shapes that are approximately constant in diameter. The tube 30 is set in the large-diameter hole 6b of the first socket 6 and the large-diameter hole 7b of the second socket 7. Since the outer diameter of the tube 30 is larger than the inner diameters of the small-diameter hole 6a of the first socket 6 and the small-diameter hole 7a of the second socket 7, the tube 30 is prevented from drop-off the socket 5.

The narrowing portion 31 is formed at the end, on the side of the first plunger 10, of the tube 30. The inner diameter of the narrowing portion 31 is larger than the diameter of the tip-side cylinder portion 11 of the first plunger 10 and smaller than the diameter of its flange portion 12, whereby as described above the first plunger 10 is prevented from drop-off the tube 30.

The narrowing portion 32 is formed at the end, on the side of the second plunger 20, of the tube 30. The inner diameter of the narrowing portion 32 is larger than the diameter of the tip-side cylinder portion 21 of the second plunger 20 and smaller than the diameter of its base-side cylinder portion 22, whereby as described above the second plunger 20 is prevented from drop-off the tube 30.

The narrowing portion 33 is, in this embodiment, a curved wall that is convex inward in the radial direction of the tube 30, and constitutes an intermediate portion (having a closed circumference), in the axial direction, of the tube 30. The inner circumferential surface of the narrowing portion 33 has a slant surface (slant portion) that is inclined so as to come closer to the center line as the position goes in the direction in which the base-side cylinder portion 13 of the first plunger 10 is inserted into the tube 30 (the axial direction of the tube 30).

The one end portion of the spring 40, which is disposed inside the tube 30, is engaged with the base surface of the base-side cylinder portion 13 and the projection 13a of the first plunger 10 and its other end portion is engaged with the base surface of the base-side cylinder portion 22 and the projection 22a of the second plunger 20. At least the end surface (seating surface), on the side of the first plunger 10, of the spring 40 being in a free state is inclined with respect to a plane that is perpendicular to the longitudinal direction of the spring 40. Thus, the spring 40 applies, to the base surface of the base-side cylinder portion 13 and the projection 13a of the first plunger 10, a force in such a direction as to incline the first plunger 10 with respect to the axial direction of the tube 30. The spring 40 extends spirally inside the tube 30.

A scrub operation (wipe operation) of the first plunger 10 will be described below. FIG. 1A shows a state that the first plunger 10 is protruded at the maximum. In this state, the outer circumferential surface of the base-side cylinder portion 13 of the first plunger 10 is not in contact (not engaged) with the inner circumferential surface of the narrowing portion 33 of the tube 30. In the state of FIG. 1A, the inclination of the first plunger 10 with respect to the axial direction of the tube 30 is determined as a result of contact of the bottom end of the outer circumferential surface of the base-side cylinder portion 13 to the inner circumferential surface of the cylindrical portion of the tube 30 and contact of the top end of the outer circumferential surface of the flange portion 12 to the inner circumferential surface of the cylindrical portion of the tube 30.

To conduct an inspection using the inspection jig 1A, first, starting from the state of FIG. 1A, the inspection jig 1A is set on the inspection board 9. As a result, as shown in FIG. 1B, the contact portion 21a of the tip-side cylinder portion 21 of the second plunger 20 comes into contact with the electrode pad 9a of the inspection board 9 and the second plunger 20 retracts against the urging force of the spring 40 until its tip comes flush with the opening of the small-diameter hole 7a of the second socket 7. Subsequently, the inspection target 8 is pressed against the inspection jig 1A, whereby the first plunger 10 retracts against the urging force of the spring 40 (see FIG. 1B) while the contact portion 11a of the tip-side cylinder portion 11 of the first plunger 10 is kept in contact with the electrode pad 8a.

In a process that the first plunger 10 retracts, the bottom end of the outer circumferential surface of the base-side cylinder portion 13 goes up onto the inner circumferential surface (i.e., the slant surface that is inclined with respect to the axial direction of the tube 30) of the narrowing portion 33 of the tube 30. As a result, the inclination of first plunger 10 with respect to the axial direction of the tube 30 decreases (i.e., the posture of the first plunger 10 becomes closer to a state that it is parallel with the axial direction of the tube 30). Since the outer diameter of the base-side cylinder portion 13 is a little smaller than the minimum inner diameter of the narrowing portion 33 of the tube 30, the first plunger 10 ends up being approximately parallel with the axial direction of the tube 30.

As the inclination of the first plunger 10 decreases, the position of the contact between the contact portion 11a of the tip-side cylinder portion 11 and the electrode pad 8a of the inspection target 8 deviates. This is a scrub operation which can increase the reliability of the contact by peeling off an oxide film, dirt, or the like formed on the surface of the electrode pad 8a. In FIG. 1B, the inspection target 8, the electrode pad 8a, and the contact portion 11a of the tip-side cylinder portion 11 of the first plunger 10 immediately before the retraction of the first plunger 10 are drawn by imaginary lines and a scrub length S is shown.

In all of the state of FIG. 1A, the process that the first plunger 10 retracts, and the state of FIG. 1B, the outer circumferential surface of the tip-side cylinder portion 11 of the first plunger 10 is not in contact with the first socket 6 (not in contact with the opening of the small-diameter hole 6a) and is also not in contact with the inner circumferential edge of the narrowing portion 31 of the tube 30. Thus, no wear occurs either between the tip-side cylinder portion 11 and the first socket 6 or between the tip-side cylinder portion 11 and the inner circumferential edge of the narrowing portion 31 of the tube 30.

Wear occurs between the outer circumferential surface of the base-side cylinder portion 13 and the inner circumferential surface of the cylindrical portion of the tube 30 and the inner circumferential surface of the narrowing portion 33 because of sliding contact. However, the degree of this wear is low because the difference between the outer diameter of the base-side cylinder portion 13 and the inner diameter of the cylindrical portion of the tube 30 and the difference between the outer diameter of the base-side cylinder portion 13 and the inner diameter of the narrowing portion 33 are smaller than the difference between the outer diameter of the tip-side cylinder portion 11 and the inner diameter of the small-diameter hole 6a of the first socket 6 and the difference between the outer diameter of the tip-side cylinder portion 11 and the inner diameter of the narrowing portion 31. The degree of wear between the outer circumferential surface of the flange portion 12 and the inner circumferential surface of the cylindrical portion of the tube 30 is likewise low.

FIG. 2 is a sectional view taken along line II-II in FIG. 1B. It is seen that since the difference between the outer diameter of the base-side cylinder portion 13 of the first plunger 10 and the inner diameter of the engagement portion of the narrowing portion 33 is small, the degree of wear is low there.

This embodiment provides the following advantages:

(1) The inspection jig 1A is configured so that in a process that the first plunger 10 retracts being in contact with the electrode pad 8a of the inspection target 8, the base-side cylinder portion 13 comes into contact with (goes up onto) the slant surface of the inner circumferential surface of the tube 30 (i.e., the inner circumferential surface of the narrowing portion 33) and the inclination of the first plunger 10 with respect to the axial direction of the tube 30 thereby varies (decreases). Thus, it is not necessary to cause the outer circumferential surface of the tip-side cylinder portion 11 and the opening of the small-diameter hole 6a of the first socket 6 to slide on each other in a contact state. Likewise, it is not necessary to cause the outer circumferential surface of the tip-side cylinder portion 11 and the inner circumferential edge of the narrowing portion 31 of the tube 30 to slide on each other in a contact state. As a result, the degree of wear that occurs between the tip-side cylinder portion 11 and the first socket 6 and between the tip-side cylinder portion 11 and the inner circumferential edge of the narrowing portion 31 of the tube 30 due to a scrub operation would be made low. More specifically, damage of the opening of the small-diameter hole 6a of the first socket 6 due to sliding contact of the tip-side cylinder portion 11 to it is suppressed, and damage of the outer circumferential surface of the tip-side cylinder portion 11 due to its sliding contact to the inner circumferential edge of the narrowing portion 31 is also suppressed.

(2) To allow the first plunger 10 to perform a scrub operation, working needs to be performed on the original member of the tube 30 to form the narrowing portion 33. However, since this working may be known drawing, the working is less difficult than in the case of related art in which a tip portion of a tube is made thicker.

(3) A scrub length would be set irrespective of the stroke length of the first plunger 10 by changing the shape of the narrowing portion 33 of the tube 30. The degree of freedom of designing is thus high.

(4) Unlike in related art, it is not necessary to form a small-diameter portion in an intermediate portion of the first plunger 10 to enable a scrub operation. Thus, this embodiment is free of a problem of reduction in strength due to formation of a small-diameter portion in an intermediate portion.

### Embodiment 2

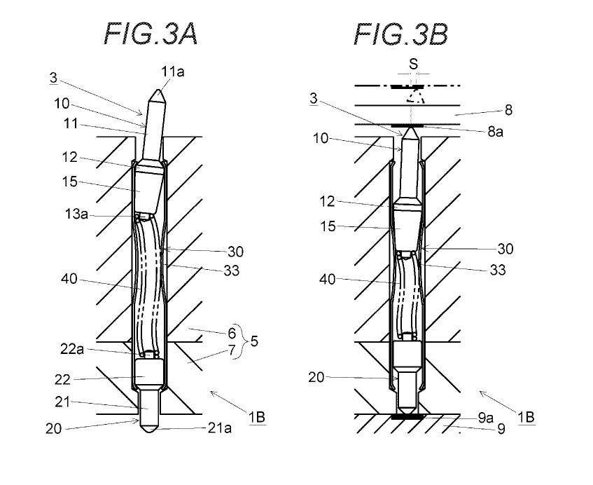

FIG. 3A is a sectional view of an inspection jig 1B according to a second embodiment. FIG. 3B is a sectional view showing how an inspection is conducted using the inspection jig 1B. The inspection jig 1B according to this embodiment is the same as the inspection jig 1A according to the first embodiment except that the base-side cylinder portion 13 of the first plunger 10 is replaced by a base-side truncated-cone portion 15. The outer circumferential surface of the base-side truncated-cone portion 15 is part of the side surface of a cone, and hence its outer diameter decreases as the position goes from the side of the flange portion 12 to the side of the spring 40. The outer diameter of the end of the base-side truncated-cone portion 15 on the side of the flange portion 12 is the same as that of the flange portion 12. This embodiment would provide the same advantages as the first embodiment.

### Embodiment 3

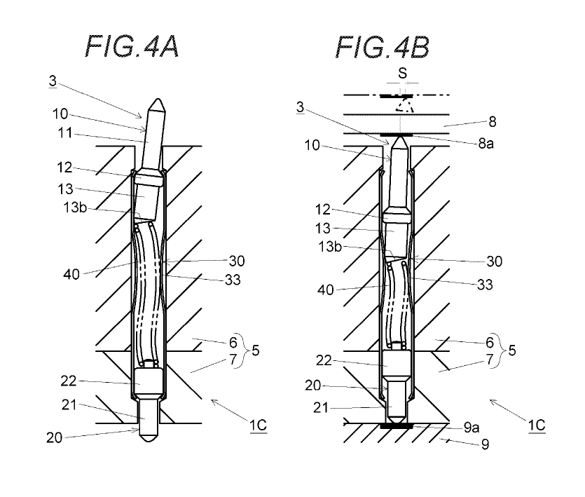

FIG. 4A is a sectional view of an inspection jig 1C according to a third embodiment. FIG. 4B is a sectional view showing how an inspection is conducted using the inspection jig 1C. The inspection jig 1C according to this embodiment is the same as the inspection jig 1A according to the first embodiment except that the projection 13a formed on the base surface of the base-side cylinder portion 13 of the first plunger 10 is absent and the base surface (slant surface 13b) is inclined with respect to the longitudinal direction of the first plunger 10 and that the two end surfaces of the spring 40 being in a free state are flat surfaces that are perpendicular to the longitudinal direction of the spring 40. This embodiment would provide the same advantages as the first embodiment.

### Embodiment 4

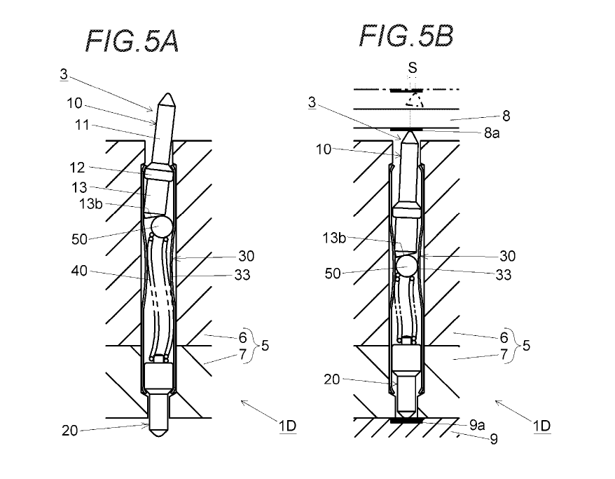

FIG. 5A is a sectional view of an inspection jig 1D according to a fourth embodiment. FIG. 5B is a sectional view showing how an inspection is conducted using the inspection jig 1D. The inspection jig 1D according to this embodiment is the same as the inspection jig 1C according to the third embodiment except that an intermediate segment 50 is interposed between the base surface (slant surface 13b) of the base-side cylinder portion 13 of the first plunger 10 and the end, on the side of the first plunger 10, of the spring 40. In this embodiment, the end surface, on the side of the first plunger 10, of the spring 40 may be either inclined or not inclined. The intermediate segment 50 is a metal sphere, for example. The urging force of the spring 40 (i.e., the force produced by its resilience) is applied to the base surface of the base-side cylinder portion 13 of the first plunger 10 via the intermediate segment 50. This embodiment would provide the same advantages as the third embodiment.

### Embodiment 5

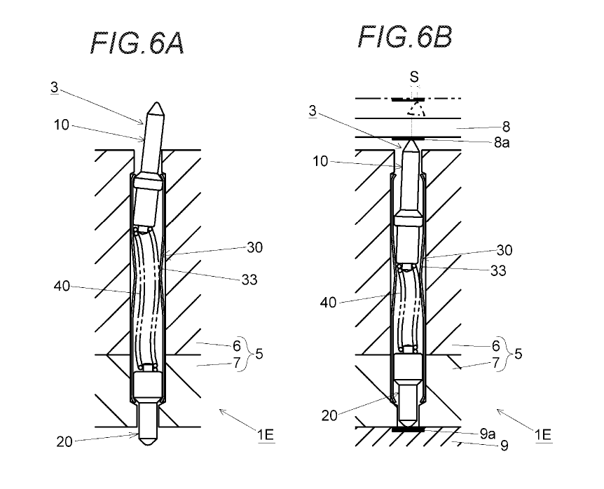

FIG. 6A is a sectional view of an inspection jig 1E according to a fifth embodiment. FIG. 6B is a sectional view showing how an inspection is conducted using the inspection jig 1E. The inspection jig 1E according to this embodiment is the same as the inspection jig 1A according to the first embodiment except that the inner circumferential surface of the narrowing portion 33 is inclined with respect to the axial direction of the tube 30 so as to extend straightly.

Where as in the first embodiment the narrowing portion 33 of the tube 30 is inclined with respect to the axial direction of the tube 30 so as to assume a curve, the scrub length variation per unit stroke length in a stroke range of the first plunger 10 that is performing a scrub operation becomes shorter as the first plunger 10 retreats. In contrast, where as in this embodiment the narrowing portion 33 is inclined with respect to the axial direction of the tube 30 so as to extend straightly, the variation of the scrub length per unit stroke length in a stroke range of the first plunger 10 that is performing a scrub operation is small.

This embodiment is suitable for a case that it is desired to make gentler the scrub length variation at a start of a scrub operation. This embodiment would provide the same advantages as the first embodiment.

### Embodiment 6

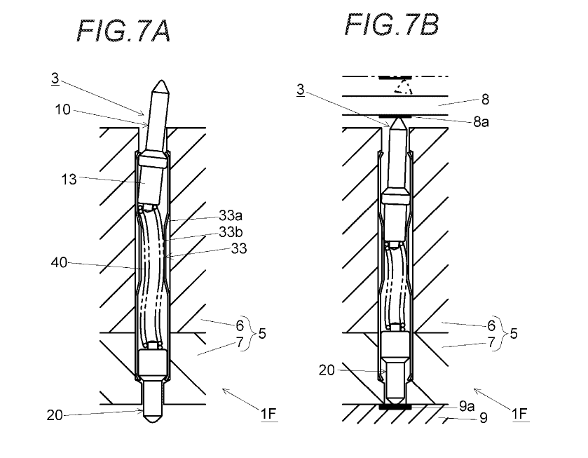

FIG. 7A is a sectional view of an inspection jig 1F according to a sixth embodiment. FIG. 7B is a sectional view showing how an inspection is conducted using the inspection jig 1F. The inspection jig 1F according to this embodiment is the same as the inspection jig 1E according to the fifth embodiment except that the inner circumferential surface of the narrowing portion 33 is inclined with respect to the axial direction of the tube 30 more steeply over a shorter distance than in the inspection jig 1E according to the fifth embodiment and that the narrowing portion 33 has a non-slant portion 33b in addition to slant portions 33a.

The inner circumferential surface of the non-slant portion 33b is parallel with the axial direction of the tube 30. In this embodiment, whereas a scrub operation occurs in that part of the stroke range of the first plunger 10 in which the base-side cylinder portion 13 goes up onto the inner circumferential surface of the slant portion 33a, no scrub operation occurs in that part of the stroke range of the first plunger 10 in which the base-side cylinder portion 13 is engaged with the inner circumferential surface of the non-slant portion 33b.

In the second half of the stroke range of the first plunger 10, the outer circumferential surface of the base-side cylinder portion 13 and the inner circumferential surface of the non-slant portion 33b are in contact with each other in such a manner as to be approximately parallel with each other, which suppresses the risk of local wear. This embodiment would provide the same advantages as the fifth embodiment.

### Comparative Example

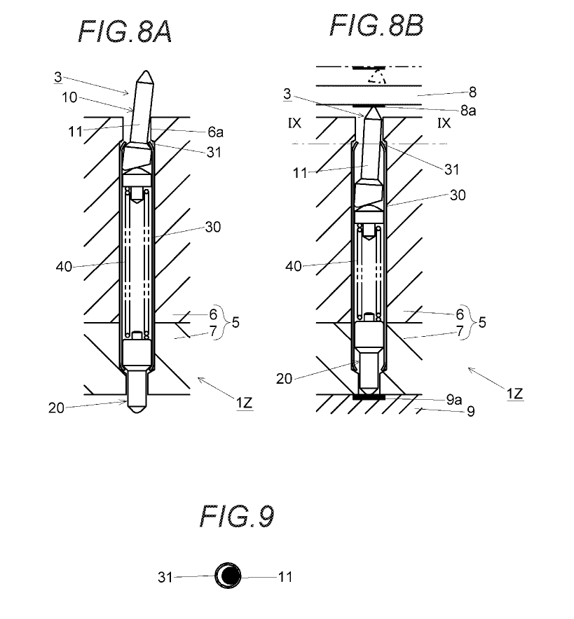

FIG. 8A is a sectional view of an inspection jig 1Z according to a comparative example alone, and FIG. 8B is a sectional view showing how an inspection is conducted using the inspection jig 1Z. The inspection jig 1Z according to the comparative example is different from the inspection jigs 1A-1F according to the above embodiments in that the tube 30 does not have the narrowing portion 33.

As a result, in the first half of the stroke range of the first plunger 10, sliding contact occurs between the outer circumferential surface of the tip-side cylinder portion 11 and the opening of the small-diameter hole 6a of the first socket 6 and the opening of the small-diameter hole 6a suffers local wear.

In the second half of the stroke range of the first plunger 10, sliding contact occurs between the outer circumferential edge of the tip-side cylinder portion 11 and the inner circumferential edge of the narrowing portion 31 of the tube 30 and the outer circumferential surface of the tip-side cylinder portion 11 suffers local wear.

FIG. 9 is a sectional view taken along line IX-IX in FIG. 8B. FIG. 9 shows that the difference between the outer diameter of the base-side cylinder portion 13 of the first plunger 10 and the inner diameter of the narrowing portion 31 of the tube 30 is large and hence local wear is prone to occur there. Each of the above-described embodiments would properly suppress local wear unlike in this comparative example.

Although the invention has been described above using the embodiments, it would be understood by those skilled in the art that the constituent elements and the process employed in each embodiment may be modified in various manners without departing from the scope of the claims. Modifications will be described below.

The invention is not limited to the case that the slant portion of the inner circumferential surface of the tube 30 is formed in an intermediate portion of the tube 30 so as to have a closed circumference by drawing, for example: it may be formed as portions of the inner circumferential surface of an intermediate portion of the tube 30, for example, as at least three projections formed at equal intervals in the circumferential direction, by, for example, groove formation working on the outer circumferential surface.

For another example, a configuration is possible in which the second plunger 20 is omitted and the other end portion of the spring 40 is in contact with the electrode pad 9 of the inspection board 9.

In accordance with the embodiments, a contact probe includes a tube which is electrically conductive, a plunger which is electrically conductive and disposed in the tube at one end of the tube, and a spring which is disposed in the tube and urges the plunger in a projection direction. The tube includes a slant portion on an inner circumferential surface of the tube. The slant portion is inclined with respect to an axial direction of the tube. A base portion comes into contact with the slant portion and an inclination of the plunger varies, when the plunger retracts.

The contact probe may be such that in a state that the plunger is projected at the maximum, the base portion of the plunger is not in contact with the slant portion and the inclination of the plunger is large; and that when the plunger retracts and the base portion comes into contact with the slant portion, the inclination of the plunger becomes small.

The contact probe may be such that the plunger is equipped with a tip-side rod-shaped portion and a drop-off-preventive large-diameter portion which are arranged in this order from the tip side; and that the tip-side rod-shaped portion is not in contact with the one end of the tube in the whole of a stroke range of the plunger.

The contact probe may be such that the spring is a coil spring; and that a rear end portion of the base portion of the plunger is engaged with an inner circumferential surface of a tip portion of the coil spring.

The contact probe may be such that an intermediate segment is interposed between a tip portion of the spring and the base portion of the plunger; and that a force produced by resilience of the spring is applied to the base portion of the plunger via the intermediate segment.

According to embodiments, an inspection jig includes any of the above contact probes; and an electrically insulative socket which holds the contact probe that penetrates through the electrically insulative socket.

The inspection jig may be such that the plunger of the contact probe is equipped with a tip-side rod-shaped portion and a drop-off-preventive large-diameter portion which are arranged in this order from the tip side; and that the tip-side rod-shaped portion is not in contact with the socket in the whole of a stroke range of the plunger.

Any combinations of the above-described constituent elements and methods, systems, etc. obtained by converting any of the above expressions of the invention are also effective modes of the invention.

### REFERENCE NUMERALS

1A-1F: Inspection jig
3: Contact probe
5: Socket
6: First socket
6a: Small-diameter hole
6b: Large-diameter hole
7: Second socket
7a: Small-diameter hole
7b: Large-diameter hole
8: inspection target
8a: Electrode pad
9: inspection board
9a: Electrode pad
10: First plunger
11: Tip-side cylinder portion
11a: Contact portion
12: Flange portion
13: Base-side cylinder portion
13a: Projection
13b: Slant surface
20: Second plunger
15: Base-side truncated-cone portion
21: Tip-side cylinder portion
21a: Contact portion
22: Base-side cylinder portion
30: Tube
31-33: Narrowing portion
40: Spring
50: Intermediate segment.

What is claimed is:

1. A contact probe comprising:
a tube which is electrically conductive;
a plunger which is electrically conductive and disposed in the tube at one end of the tube, wherein the plunger is to be electrically connected to an inspection target; and
a spring which is disposed in the tube and urges the plunger in a projection direction,
wherein the tube includes a slant portion on an inner circumferential surface of the tube,
wherein the slant portion is inclined with respect to an axial direction of the tube, and
wherein the plunger is configured that a base portion of the plunger comes into contact with the slant portion and an inclination of the plunger varies during a retracting of the plunger.

2. The contact probe according to claim 1, wherein the plunger is configured that the base portion of the plunger is not in contact with the slant portion and the inclination of the plunger is large in a state that the plunger is projected at the maximum, and
wherein the inclination of the plunger is small in the state that the plunger retracts and the base portion comes into contact with the slant portion.

3. The contact probe according to claim 1, wherein the plunger includes a drop-off-preventive large-diameter portion and a tip-side rod-shaped portion arranged in a tip side of the drop-off-preventive large-diameter portion, and
wherein the tip-side rod-shaped portion is not in contact with the one end of the tube over a whole stroke range of the plunger.

4. The contact probe according to claim 1, wherein the spring includes a coil spring, and
wherein a rear end portion of the base portion of the plunger is engaged with an inner circumferential surface of a tip portion of the coil spring.

5. The contact probe according to claim 1, further comprising:
an intermediate segment interposed between a tip portion of the spring and the base portion of the plunger, wherein a force produced by the spring is applied to the base portion of the plunger through the intermediate segment.

6. The contact probe according to claim 1, wherein, in the slant portion, an inner diameter of the tube becomes lager toward the one end of the tube.

7. An inspection jig comprising:
the contact probe according to claim 1; and
an electrically insulative socket which holds the contact probe that penetrates through the electrically insulative socket.

8. The inspection jig according to claim 7, wherein the plunger includes a drop-off-preventive large-diameter portion and a tip-side rod-shaped portion arranged in a tip side of the drop-off-preventive large-diameter portion, and
wherein the tip-side rod-shaped portion is not in contact with the one end of the tube over a whole stroke range of the plunger.
